(19) United States
(12) Patent Application Publication
(10) Pub. No.: US 2026/0221675 A1
(43) Pub. Date: Jul. 30, 2026

(54) PIN FOR TRANSFER MOLDED SEMICONDUCTOR DEVICE PACKAGE

(71) Applicant: SEMICONDUCTOR COMPONENTS INDUSTRIES, LLC, Scottsdale, AZ (US)

(72) Inventors: Atapol PRAJUCKAMOL, Thanyaburi (TH); Chee Hiong CHEW, Seremban (MY)

(73) Assignee: SEMICONDUCTOR COMPONENTS INDUSTRIES, LLC, Scottsdale, AZ (US)

(21) Appl. No.: 19/038,558

(22) Filed: Jan. 27, 2025

(51) Int. Cl. H01R 4/48; H01L 23/538; H01L 25/00; H01L 25/07

(52) U.S. Cl. CPC H01R 4/4863; H10W 70/60; H10W 70/611; H10W 90/00

(57) ABSTRACT

An apparatus includes a base, a tip, and a body region disposed between the base and the tip. The apparatus further includes a flange disposed on a top of a moving component and a biasing component coupled to the moving component. The moving component is configured to slide on the body region, and the biasing component is configured to bias the flange upward against a surface.

### TECHNICAL FIELD

This description relates to assembling and packaging semiconductor device modules, semiconductor device assemblies, and semiconductor devices. More specifically, this description relates to transfer molded semiconductor device module packages.

### BACKGROUND

Semiconductor device assemblies (e.g., chip assemblies), which include power semiconductor devices can be implemented using multiple semiconductor dies, substrates (e.g., die attach pads (DAPs)), electrical interconnections, and a molding compound. Power transistors can include, for example, insulated-gate bipolar transistors (IGBTs), power metal-oxide-semiconductor field effect transistors (MOSFETs), and so forth. Fast recovery diodes (FRDs) may be used in conjunction with power transistors. Electrical interconnections within a high-power semiconductor device module can include, for example, bond wires, conductive spacers, and conductive clips. A polymer molding compound can serve as an encapsulant to protect components of the device assembly. Such high-power chip assemblies, encapsulated as semiconductor device modules, can be used in various applications, including electric vehicles (EVs), hybrid electric vehicles (HEVs), and other industrial applications.

### SUMMARY

In an aspect, an apparatus includes a base, a tip, and a body region disposed between the base and the tip. The apparatus further includes a flange disposed on a top of a moving component and a biasing component coupled to the moving component. The moving component is configured to slide on the body region, and the biasing component is configured to bias the flange upward against a surface.

In an aspect, an apparatus includes a base, a tip, and a body region disposed between the base and the tip. The body region has a cylindrical shape. The apparatus further includes a flange disposed on a top of a deformable moving component that is configured to slide on the body region. The deformable moving component in a deformed state is in a fixed position to bias the flange upward against a surface.

In an aspect, a power circuit includes a chip assembly disposed on a top surface of a direct bond metal (DBM) substrate. The power circuit further includes a first metal strip having a first end extending beyond a first edge of the DBM substrate as a negative direct current power terminal disposed at the first edge. The first metal strip has multiple parallel extensions extending from the first edge to respective second ends attached to the DBM substrate. The power circuit further includes a second metal strip having a first end extending beyond the first edge of the DBM substrate as a positive direct current power terminal disposed at the first edge. The second metal strip has multiple parallel extensions extending from the first edge to respective second ends attached to the DBM substrate. The power circuit further includes a third metal strip having a first end extending beyond a second edge of the DBM substrate, opposite the first edge, as an alternating current power terminal disposed at the second edge. The third metal strip has multiple parallel extensions extending from the second edge to respective second ends attached to the DBM substrate. The first, second, and third metal strips confine current in the power circuit to flow in parallel paths along the respective multiple parallel extensions.

The power circuit of further includes at least one signal pin attached, in a vertical orientation, to a trace on the DBM substrate.

In an aspect, a method includes inserting a pin in an opening in a mold cavity block in a mold chase, sliding a flange over a body region of the pin, and biasing the flange against a surface of the mold cavity block surrounding the opening therein.

In some example implementations, the flange is attached to a top of a moving component, and biasing the flange against the surface of the mold cavity block includes disposing a spring on the moving component and compressing the biasing component to bias the flange against the surface of the mold cavity block.

In some example implementations, compressing the biasing component to bias the flange against the surface of the mold cavity block includes holding the biasing component in a compressed state utilizing a biasing component stopper attached a base region of the pin.

In some example implementations, the flange is attached to a top of a moving component that is deformable, and biasing the flange against the surface of the mold cavity block includes deforming the moving component to hold it in a fixed position while the flange attached to the top of the moving component is contacting the surface of the mold cavity block.

In an aspect, a method includes disposing a chip assembly and components on a direct bond metal (DBM) substrate to form a power circuit.

The method further includes disposing metal strips on the power circuit. The metal strips have first ends that extend beyond edges of DBM substrate to serve as external terminals of the power circuit when encapsulated in a molded package. Each metal strip has multiple parallel extensions with respective second ends. The method further includes attaching the respective second ends of the metal strips to the DBM substrate, and attaching a signal pin in a vertical orientation to a trace on the DBM substrate. The signal pin includes a flange attached to a top of a moving component sliding on a body region of the signal pin.

The method further includes disposing the DBM substrate on which the power circuit is formed on a top of a bottom mold cavity in a mold cavity chase, disposing a top cavity block on top of the DBM substrate to form a top mold cavity, and aligning and inserting the signal pin in an opening extending through the top cavity block. The method further includes biasing a flange attached to a top of the moving component to press against a surface of the top cavity block.

The method further includes injecting fluid mold material in at least the top mold cavity, and after the fluid mold material is cured and set, removing the top cavity block.

The foregoing illustrative summary, as well as other objectives and/or advantages of the disclosure, and the manner in which the same are accomplished, are further explained in the following detailed description, and accompanying drawings.

### BRIEF DESCRIPTION OF THE DRAWINGS

FIG. 1A illustrates an example pin extending vertically from a substrate that is encapsulated in a liquid mold compound in a transfer or injection molding process.

FIG. 1B and FIG. 1C illustrate example pins that include a biasing component (e.g., a spring-loaded flange) to seal an opening (e.g., hole) in a top mold cavity block of a mold chase in a transfer or injection molding process.

FIGS. 2A, 2B and 2C schematically illustrate example positions of a pin (e.g., the pin of FIG. 1A through FIG. 1C) in portions of a mold form or chase before and during a transfer molding process.

FIG. 3A and FIG. 3B illustrate example pins that include a deformable moving component that can be deformed to bias a flange attached to a top of the moving component to seal the opening in a transfer or injection molding process.

FIGS. 4A, 4B, and 4C schematically illustrate example positions of a pin (e.g., the pin of FIG. 3A) in portions of a mold form or chase before and during a transfer molding process.

FIG. 5A is a perspective top view of a power circuit fabricated on a substrate, according to implementations of the present disclosure.

FIG. 5B is a perspective top view of a mold casing of a package encapsulating a power circuit, according to implementations of the present disclosure.

FIG. 5C is a perspective bottom view of the mold casing of FIG. 5B, according to implementations of the present disclosure.

FIG. 6 illustrates an example method for preventing or reducing mold bleed around a pin that extends through an opening in a mold cavity block during a lateral or injection molding process.

FIG. 7A illustrates a method for fabricating a power circuit, according to implementations of the present disclosure.

FIG. 7B illustrates a method for packaging the power circuit in a molded casing, in accordance with some implementations of the present disclosure.

Aspects of the present disclosure are best understood from the following detailed description when read in conjunction with the accompanying figures. It is noted that, in accordance with general practice in the field, various features are not necessarily drawn to scale. Dimensions of the various features may be arbitrarily increased or reduced for clarity in visualization and discussion. In the drawings, like reference symbols may indicate like and/or similar components (elements, structures, etc.) in different views. The drawings illustrate generally, by way of example, but not by way of limitation, various implementations discussed in the present disclosure. Reference symbols or numerals shown in one drawing may not be repeated for the same, and/or similar elements in related views. Reference symbols or numerals that are repeated in multiple drawings may not be individually discussed with respect to each of those drawings but are provided for context between related views. Also, not all elements in the drawings may be specifically identified with a reference symbol or numeral when multiple instances of an element are illustrated.

### DETAILED DESCRIPTION

The footprint of an electronic device and/or circuit is important with respect to materials cost and reliability. When electronic devices (e.g., high-power semiconductor devices or circuits) are laid out in an inefficient manner, wasted space on a substrate increases material cost unnecessarily. In addition, wiring between devices that are spaced apart can be inherently more vulnerable to damage or breakage and, consequently, can cause reliability failures. These concerns are particularly significant for high power circuits that include expensive materials such as silicon carbide (SiC), high tech ceramics made of silicon nitride (Si₃N₄), and direct bond metal (DBM) substrates (e.g., direct bond copper (DBC) substrates) for the high power circuits. A DBM substrate can have a multi-layer structure including a conductive top metal layer, an electrically insulating layer, and a conductive bottom metal layer. When these high power circuits are manufactured in large volume, even a small reduction in per unit cost can add up to a substantial saving.

Semiconductor packaging is a crucial aspect of electronics manufacturing that involves enclosing semiconductor chips and circuits in protective and functional packages to ensure their reliability, performance and integration into electronic systems. These packages serve as a bridge between the tiny, sensitive semiconductor chips and the broader electronic systems, providing electrical connections, thermal management, and environmental protection.

Molding is the process of packaging (encapsulating) the device circuit or module in hard plastic material or epoxy. Transfer or injection molding is a widely used molding process in the semiconductor industry. In this process, the device circuits and substrates to be encapsulated are placed in mold cavities in a mold form or chase. A molding compound in a fluid state (molten) is forced by a hydraulic plunger into the runners of the mold chase. These runners serve as canals through which the fluid mold compound travels until it reaches the mold cavities, which contain the device circuit or module and substrates to be encapsulated. The mold form or chase may include a top mold cavity block and a bottom mold cavity block, which respectively define an upper surface and a lower surface of the mold cavity that is filled with fluid mold compound to encapsulate the object (e.g., the device circuit or module) placed in the mold cavity.

This disclosure relates to implementations, for example, of a molded package for a high-power device circuit or module fabricated, for example, on a (direct bonded metal (DBM) substrate. The package may, for example, be a single side direct cooling (SSDC) package. The device circuit or module may route large currents through a set of metal power tabs instead of passing high currents through the DBM substrate. The metal power tabs (e.g., a DC+ power tab and a DC − power tab) extending from the package may be oriented and closely spaced to reduce stray inductance and resistance, thereby improving performance while simultaneously reducing the footprint of the device circuit or module. In addition, wire bonds between chip assemblies in the device circuit or module can be replaced by solid metal clips that can better withstand high currents and voltages. The SSDC package may incorporate the metal power tabs and provide additional heat dissipation via a metal base plate that includes a heat sink. The heat sink can be immersed in a cooling fluid to provide faster heat dissipation.

Further, the device circuit or module may include signal pins or leads that can provide, for example, physical connections between the device circuit or module and external circuits (e.g., using vias or openings (e.g., holes) in a circuit board, or a plug-in connector of the external circuits). The signal pins, which are attached to a circuit on the DBM substrate and extend through the package, can form the external electrical connections (e.g., power supply, signal, and ground leads (terminals)) to the enclosed device circuit or module. In example implementations, these signal pins may extend vertically through the molded package.

A vertically-oriented pin (soldered or sintered to the DBM substrate) may extend through an opening (e.g., a hole) in a top mold cavity block in a mold form or chase used in the transfer molding process. This opening in the top mold cavity block (or layer) may have a diameter that is larger than a diameter of the vertically-oriented pin, for example, to accommodate tolerances in the lateral positioning and/or tolerances in the diameter of the vertically-oriented pin.

The present disclosure describes pins with fixtures or adaptors for sealing the openings through which vertically-oriented pins pass in molded device or circuit packages. The fixtures or adaptors are configured to avoid leakage or seepage of the fluid mold compound (e.g., mold bleed) around the vertical signal pins on to the top of the package during a transfer molding process.

A pin may have a base region, a tip region, and a body region between the base region and the tip region. In example implementations, the pin may be made of metal (e.g., copper (Cu), aluminum (Al) or a metal alloy).

In general, the body region may have a cylindrical shape (e.g., a rod-like shape) and may determine a functional length of the pin. In some implementations, the body region may have a shape other than a cylindrical shape (e.g., a square profile or cross-sectional shape, a non-circular cross-sectional shape). The tip region may have a compressible structure (e.g., a taper, a needle eyelet structure, etc.) configured to allow the pin to be, for example, press fit, in a circuit board or connector of a receiving electronic system. The base region may include a shape (e.g., a plate-like shape, a tab) configured to allow the base region to be attached (e.g., soldered, sintered, or welded) to a trace on a device or circuit substrate.

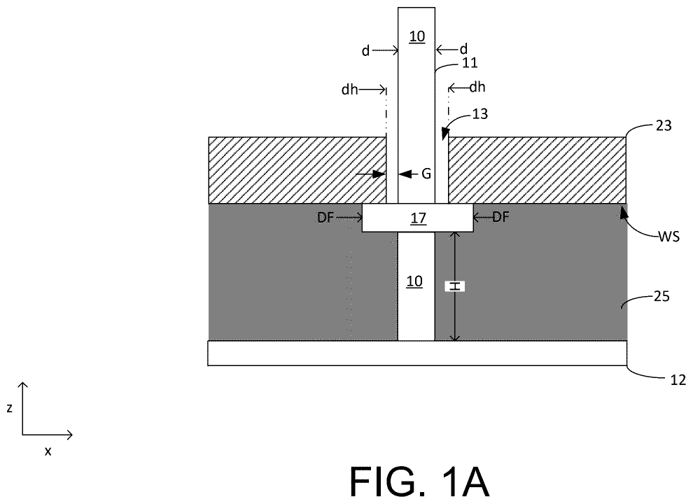

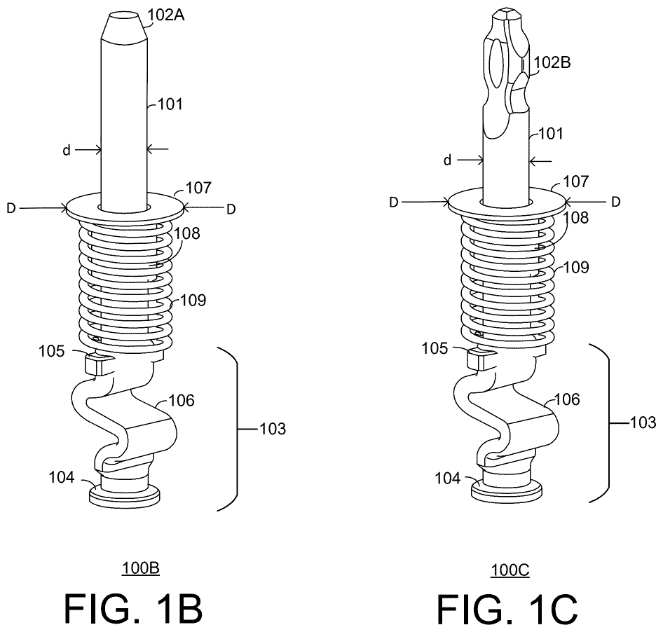

FIG. 1A illustrates an example pin 10 extending (e.g., vertically in the z direction) from a substrate 12 that is encapsulated in a liquid mold compound 25 in a transfer or injection molding process. The pin 10 can be configured to provide, for example, physical connections between the device circuit or module and external circuits (e.g., using vias or openings (e.g., holes) in a circuit board, or a plug-in connector of the external circuits).

In some implementations, the pin 10 may have a cylindrical body 11 having a diameter d. In some implementations, the cross-sectional shape of the pin 10 can be different from a cylinder (e.g., square shaped, etc.). In the molding process, cylindrical body 11 of pin 10 passes through a hole 13 (e.g., with a diameter dh) in a wall 23 of a mold chase or form into which liquid mold compound 25 is injected. The diameter dh of hole 13 can be larger than the diameter d of the cylindrical body 11 of pin 10. This may result in a gap G between the sides of pin 10 and the sides of the hole 13 through which liquid mold compound 25 may bleed through (e.g., in the z direction) across wall 23. To prevent this mold bleed, a flange 17 (or washer) having a diameter DF greater than diameter dh) may be used to cover gap G. The flange or washer may be placed flush with a bottom surface (WS) of wall 23. In some example implementations, flange 17 may be permanently attached to the cylindrical body of pin 10 (e.g., at fixed height H from substrate 12). In some other example implementations, flange 17 may be slidable between different heights on body 10 before the molding process. A biasing mechanism (not shown in FIG. 1A) may be used to bias flange 17 flush against surface WS in the molding process.

In example implementations, a pin is provided with a biased (e.g., spring-loaded) flange (e.g., annular disk) to seal an opening (e.g., a hole) in a top mold cavity block through which the pin may be placed in a transfer or injection molding process. In some implementations, the flange may be attached to a top of a moving component (e.g., an annular bushing, a tubular bushing), which can move (e.g., slide) on the body region. A biasing component (e.g., a helical wire spring wound) disposed on the moving component may bias the flange upward to contact (e.g., press against) a surface of the top mold cavity block to seal the opening in a top mold cavity block.

FIG. 1B and FIG. 1C show example pin 100B and pin 100C, respectively, that include a biasing component (e.g., a spring-loaded flange) to seal the opening in a top mold cavity block of a mold chase through which the pin may be placed in a transfer or injection molding process.

As shown in FIG. 1B and FIG. 1C, both pin 100B and pin 100C include a body region 101 (e.g., a cylindrical body region). In example implementations, body region 101 may be a rod-like structure having a cylindrical, oval, square, or rectangular cross-section. In some implementations, body region 101 may have a cylindrical rod-like shape with a diameter “d”. A flange 107 may be attached to a top of a moving component 108 (e.g., a sliding component, an annular bushing (e.g., bushing)) which can be placed over, and slid along a length of body region 101. The flange and or the moving component may be made of plastic, metal, or a metal alloy. Flange 107 may have an outer diameter D that is larger than the diameter d of body region 101 and also larger than a diameter (not shown in FIG. 1B and FIG. 1B) of the opening in the top mold cavity block of the mold chase). A biasing component 109 (e.g., a wire spring (e.g., a helical wire spring)) may bias flange 107 against a surface of the top mold cavity block to seal the opening through which the pin (pin 100B or pin 100C) is positioned. The flange and/or the biasing component may be made of plastic, metal or a metal alloy. In some implementations, the flange 107 can be referred to as a tab or as a protrusion.

In pin 100B, body region 101 extends between a tip region 102A, which has a compressible structure (e.g., a compressible tapered structure), and a base region 103. In pin 100C, body region 101 extends between a tip region 102B, which has a compressible needle eyelet structure, and base region 103. The tip regions (tip region 102A and tip region 102B) may be configured to be press-fit in receiving openings in circuit boards or connectors.

In example implementations, in both pins (pin 100B, and pin 100C), a base region (base region 103) is attached to a bottom of body region 101. In example implementations, base region 103 may include, for example, a flexible structure 106 (e.g., an S-shaped ribbon) extending from a biasing component stopper 105 (also can be referred to as a tab) to a base 104. Base 104 may include a flange (e.g., tab) configured to be attached (e.g., soldered, sintered) to a trace on the device or circuit substrate being encapsulated. In some implementations, biasing component stopper 105 may be a latch or other mechanism that locks biasing component 109 in place. Biasing component stopper 105 (e.g., latch or other mechanism) may be a lateral extension (e.g., a bar or a shoulder) attached to a top of a flexible structure 106. Biasing component stopper 105 may have a width (not shown) that is the same as or larger than a diameter of biasing component 109. Biasing component stopper 105 may be configured to provide support to, or lock the biasing component 109 in a compressed position for biasing moving component 108/flange 107 upward on body region 101.

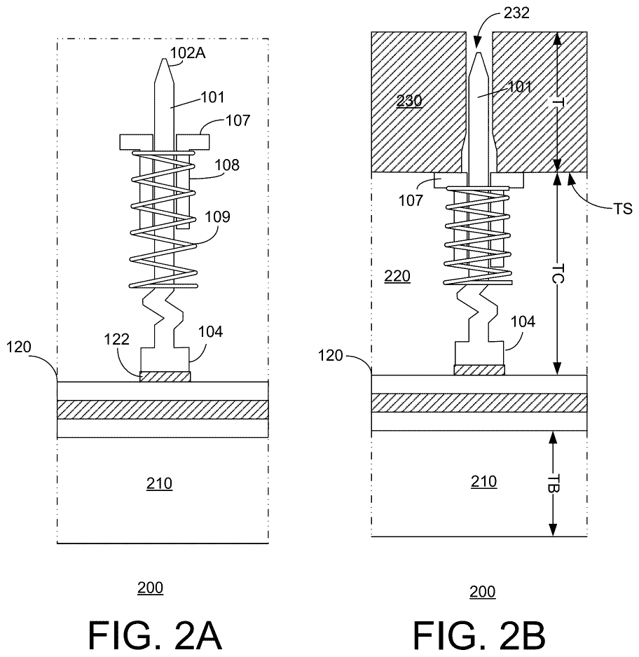

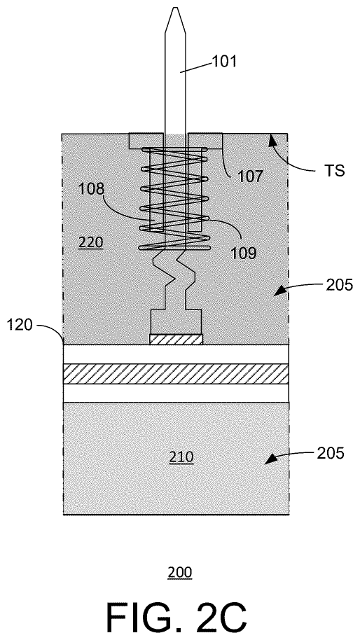

FIGS. 2A, 2B and 2C schematically show example positions of a pin (e.g., pin 100B) in portions of a mold form or chase 200 before and during a transfer molding process. These figures show only a vertical section of chase 200 (e.g., mold chase) including pin 100B.

FIG. 2A shows pin 100B attached to a substrate (e.g., DBM substrate 120). DBM substrate 120 (which can be referred to as a substrate) may be placed above a bottom mold cavity 210 in chase 200. Bottom mold cavity 210 may have a thickness TB. Pin 100B in a vertical orientation may be attached to DBM substrate 120 by a layer of solder 122 (or sintered material) between base 104 of pin 100B and the DBM.

Further, as shown in FIG. 2B, a top mold cavity block 230 may be disposed in a mold form or chase above DBM substrate to define a top mold cavity 220. Top mold cavity block 230 may have a thickness T. A bottom surface TS of top mold cavity block may form a top surface of top mold cavity 220.

Top mold cavity block 230 may have an opening 232 extending through its thickness T. The top mold cavity block may be aligned so that pin 100B (e.g., vertically-aligned pin) attached to DBM substrate 120 extends into opening 232. In example implementations, opening 232 may be tapered to have a larger diameter in a bottom portion of the top mold cavity block and a smaller diameter in an upper portion of the top mold cavity block. The larger diameter of opening 232 in the bottom portion of the top mold cavity block may enable a greater tolerance for variations in pin position. The smaller diameter on DBM substrate 120. The smaller diameter of opening 232 in the upper portion of the top mold cavity block may aid in precise positioning of the pin.

As shown in FIG. 2B, biasing component 109 on pin 100B (e.g., vertically-aligned pin) may bias flange 107 against the bottom surface TS of the top mold cavity block to seal opening 232 around pin 100B. This may prevent fluid mold material that may be injected into top mold cavity 220 from bleeding into opening 232.

In example implementations, in a transfer molding process, a fluidic form of the mold compound 205 can be injected in chase 200 to fill bottom mold cavity 210 and the top mold cavity 220. The fluid mold compound in the mold cavities may be then cured or set.

Then, as shown in FIG. 2C, the top mold cavity block 230 can be removed to leave DBM substrate 120 encased in the mold compound 205 with body region 101 and tip region 102A of pin 100B (e.g., vertically-aligned pin) extending above the top surface TS of the top mold cavity.

In the example pins shown in FIGS. 1A and 1B, a flange 107 (e.g., an annular flange or disc attached to moving component 108) is biased against a bottom surface of the top mold cavity block by a biasing component 109 (e.g., spring). Further, mold cavity block may also be biased against flange 107 by a weight or a clamp (not shown) on the mold casing.

In other implementations, flange 107 may be attached to a deformable moving component. The deformable moving component may be deformed (e.g., flared) and friction fit on a tapered portion (die portion) of the body region 101 to prevent its movement and to bias flange 107 against the bottom surface of the top mold cavity block.

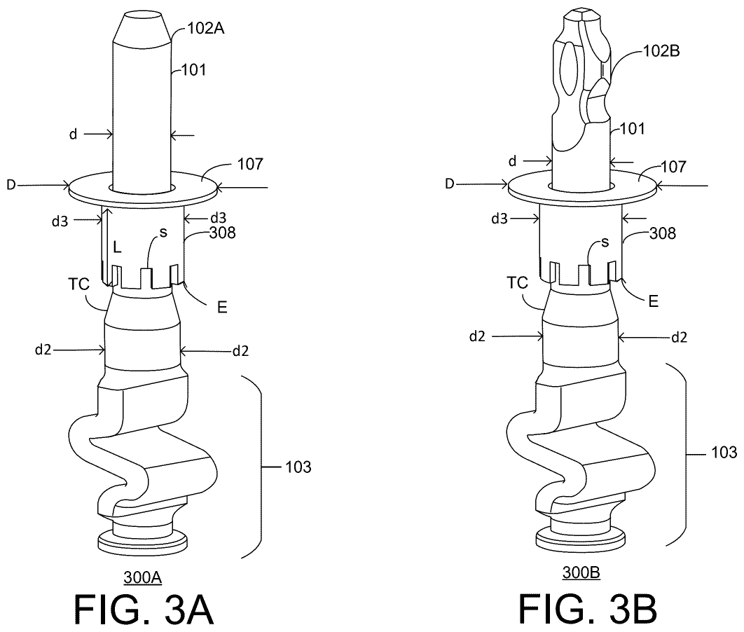

FIG. 3A and FIG. 3B show example pin 300A and pin 300B, respectively, that include a deformable moving component that can be deformed to bias a flange attached to the top of the moving component to seal the opening in a top mold cavity block of the mold chase through which the pin may be placed in the transfer or injection molding process.

As shown in FIG. 3A and FIG. 3B, both pin 300A and pin 300B include a body region 101. Body region 101 may have a cylindrical rod-like shape with an upper portion having a diameter “d”. A lower portion of the body region may have a taper TA (taper portion) increasing to a diameter “d2” before merging into base region 103. A flange 107 may be attached to a top of a moving component 308 (e.g., bushing), which can be placed over, and slid along a length of body region 101.

Flange 107 may have an outer diameter D that is larger than the diameter d of body region 101 and also larger than a diameter (not shown in FIG. 3A and FIG. 3B) of the opening in the top mold cavity block of the mold chase). Moving component 308 may have an annular tube-like structure with a length L and a diameter d3 (inner diameter). A lower edge E of moving component 308 may be slit, for example, with slits S running parallel to the length of the moving component. These slits may allow the annular tube-like structure of the moving component to be deformed (e.g., flared outward) when the moving component is slid over taper TA while flange 107 is contacting (e.g., pressing against) a top mold cavity block.

The diameter d3 of moving component 308 may be larger than diameter d of the upper portion of body region 101, but in an unflared state of moving component 308 the diameter d3 of moving component 308 may be smaller than diameter dd of the lower portion of body region 101.

In a flared state with the edge E of moving component 308 even when partially slid over taper TA in a friction fit, moving component 308 may act to bias flange 107 upward against a top mold cavity block.

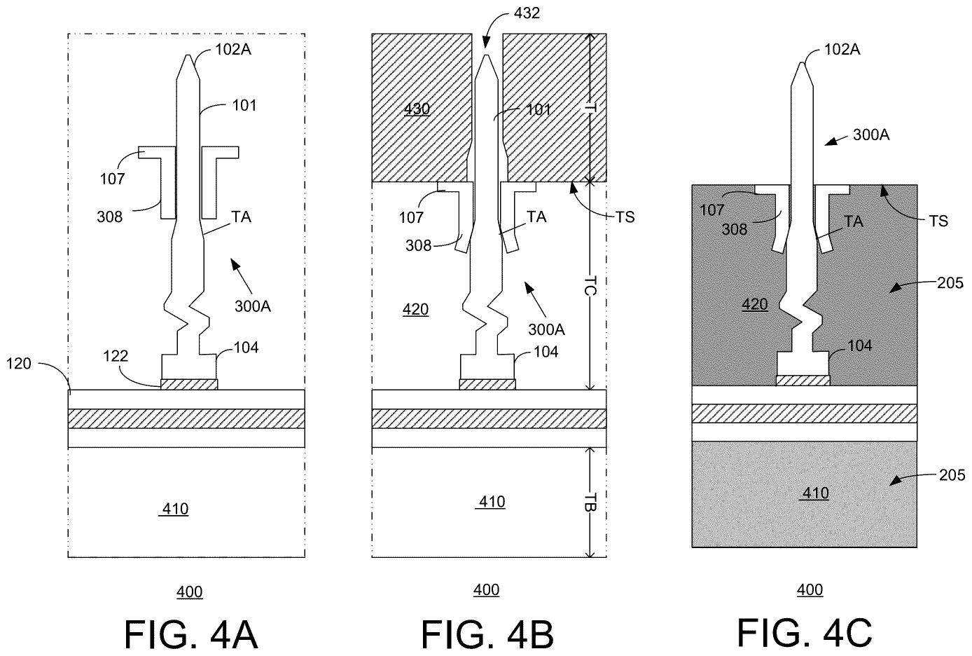

FIGS. 4A, 4B, and 4C schematically show example positions of a pin (e.g., pin 300A) in portions of a mold form or chase 400 (e.g., mold chase) during a transfer molding process. These figures only show a vertical section of chase 400 including pin 300A.

FIG. 4A shows pin 300A attached to a substrate (e.g., DBM substrate 120). DBM substrate 120 may be placed above a bottom mold cavity 410 in chase 400. Bottom mold cavity 410 may have a thickness TB. Pin 300A in a vertical orientation may be attached to DBM substrate 120 by a layer of solder 122 (or sintered material) between base 104 of pin 300A and the DBM substrate.

Further, as shown in FIG. 4B, a top mold cavity block 430 may be disposed in a mold form or chase 400 above DBM substrate to define a top mold cavity 420. Top mold cavity block 430 may have a thickness T. A bottom surface TS of the top mold cavity block may form a top surface of top mold cavity 420.

Top mold cavity block 430 may have an opening 432 extending through its thickness T. The top mold cavity block may be aligned so that pin 300A (e.g., vertically-aligned pin) attached to DBM substrate 120 extends into opening 432. In example implementations, opening 432 may be tapered to have a larger diameter in a bottom portion of the top mold cavity block and a smaller diameter in an upper portion of the top mold cavity block. The larger diameter of opening 432 in the bottom portion of the top mold cavity block may enable a greater tolerance for variations in pin position. The smaller diameter of opening 432 in the upper portion of the top mold cavity block may aid in precise positioning of the pin.

As shown in FIG. 4B, moving component 108 may be pressed on to taper TA and flared for a friction fit on taper TA. The friction fit may hold moving component 308 in its flared state in a fixed position and may bias flange 107 against the bottom surface TS of the top mold cavity block to seal opening 432 around pin 300A. Further, the top mold cavity block 430 itself may be biased against flange 107 by a weight or a clamp (not shown) on mold form or chase 400. This may prevent fluidic mold material that may be injected into top mold cavity 420 from bleeding into opening 232.

In example implementations, in a transfer molding process, a fluidic state of the mold compound 205 can be injected in chase 400 to fill bottom mold cavity 410 and the top mold cavity 420. The fluid mold compound in the mold cavities may be then cured or set. Then, as shown in FIG. 4C, the top mold cavity block 430 can be removed to leave DBM substrate 120 encased in a mold body. The mold body may be made of mold compound 205 with a portion of body region 101 and tip region 102A of pin 300A (e.g., vertically-aligned pin) extending above the top surface TS of the top mold cavity.

The pins described in the foregoing (e.g., pin 100B, FIG. 1B; pin 100C, FIG. 1B; Pin 300A, FIG. 3A; and pin 300B, FIG. 3B) may be used to provide vertically-aligned pins in a molded package of any type semiconductor devices or circuits assembled in any type of semiconductor material on any type of substrate.

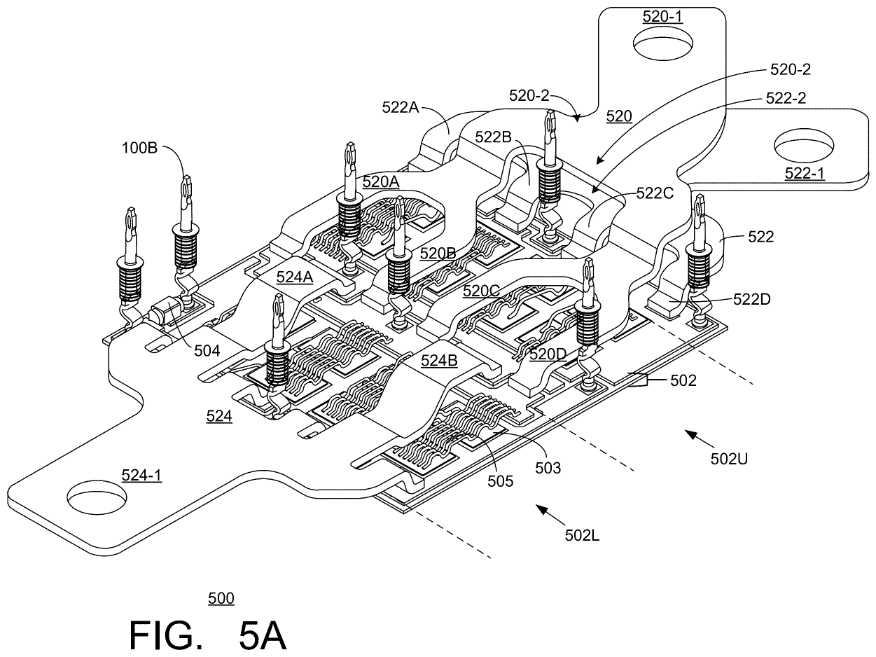

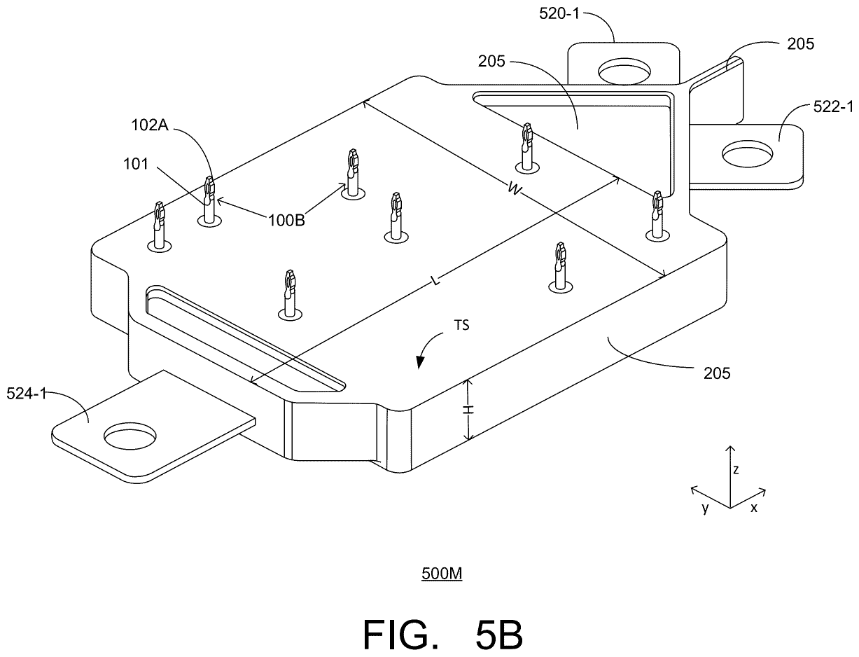

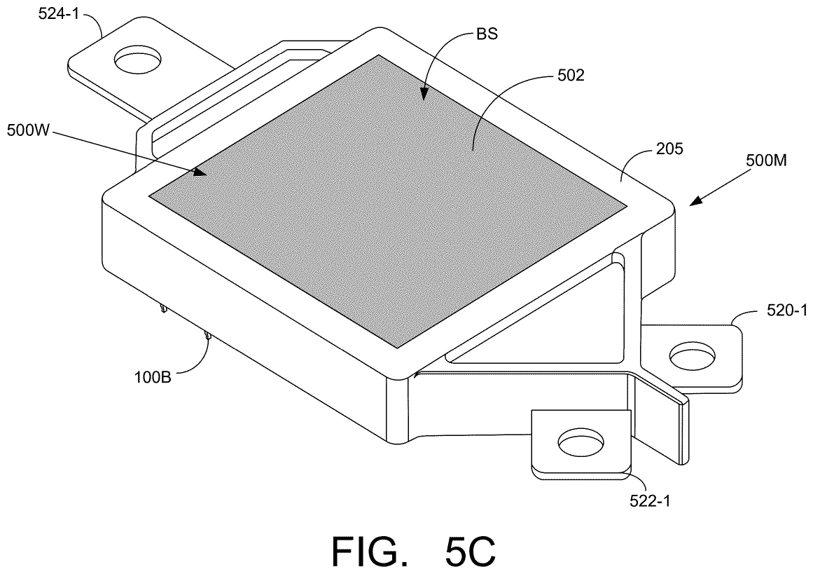

FIG. 5A shows, for example, a perspective top view of a power circuit 500 fabricated on a DBM substrate 502 that may be enclosed in a molded package with vertically aligned pins extending externally from the molded package, according to implementations of the present disclosure. Power circuit 500 fabricated on DBM substrate 502 may be encapsulated in a molded package (e.g., molded casing 500M, FIG. 5B).

Power circuit 500 (e.g., a power inverter circuit) may include electronic components (e.g., semiconductor dies or chip assembly 503, thermistor 504, etc.). In example implementations, the chip assembly 503 can be attached to (e.g., mounted on, or coupled to) a top surface of a DBM substrate 502 by a copper sputtering process or by a bonding agent, e.g., an epoxy, a solder, a sinter process, a silver (Ag) sintering material, and/or an adhesive. In some implementations, many chip assemblies like chip assembly 503 can be included in the power circuit 500. In example implementations, several chip assemblies, such as chip assembly 503, are interconnected, for example, by wire bonds 505 or conductive metal clips (not shown).

In some implementations that include multiple chip assemblies, chip assembly 503 can include, for example, high power semiconductor devices such as an insulated-gate bipolar transistor (IGBT) and a controller configured to control the IGBT. The chip assembly may be coupled to a temperature-measuring thermistor (e.g., thermistor 504) that may, for example, be mounted on DBM substrate 502. The controller can also serve as a protection device for the IGBT. For example, the controller can provide temperature protection and/or over-voltage protection for the IGBT. The controller can also limit the amount of current delivered to the IGBT. In some implementations, the controller can be configured to monitor the IGBT. In some implementations, other types of semiconductor dies, e.g., MOSFETs, diodes, and so forth, can be used as one or more of the chip assembly 503. In some implementations, fast recovery diodes (FRDs) may be used in conjunction with power transistors.

The chip assembly 503 may be fabricated on various types of semiconductor substrates, e.g., semiconductor wafers, for example, silicon (Si), silicon carbide (SiC), gallium (Ga) compounds (such as gallium nitride (GaN), aluminum gallium nitride (AlGaN), gallium arsenide (GaAs), aluminum gallium arsenide (AlGaAs), etc.), indium phosphide (InP), glass substrates, sapphire substrates, and so on. In general, any type of semiconductor chip can be fabricated on any type of substrate.

In some implementations, different types of chip assemblies (e.g., chip assembly 503 (or different devices therein)) can be fabricated on different substrates in a hybrid configuration. For example, an IGBT chip assembly can be fabricated on a SiC substrate, while a controller chip assembly can be fabricated on a silicon substrate. In some implementations as described herein, multiple chip assemblies can be fabricated on the same substrate, e.g., on a SiC substrate, suitable for high power applications.

Power circuit 500 may include metal strips (e.g., metal strip 520, metal strip 522 and metal strip 524) that have first ends that extend beyond the edges of substrate as power tabs forming the external terminals of the power circuit 500 encapsulated in a molded package (e.g., molded casing 500M, FIG. 5B). Each metal strip may have multiple second ends. The second ends of metal strips may be attached (e.g., soldered or welded) at various locations to the substrate. In some implementations, the metal strips (e.g., metal strip 520, metal strip 522, and metal strip 524) can be made of a thick metal, about 1.0 mm thick, capable of supporting high voltages in a range of about 600 V to about 1700 V and carrying high currents up to about 900 A.

In some implementations, a first power tab 520-1 and a second power tab 522-1 are disposed on one end of the DBM substrate 502 and the third power tab 524-1 is disposed on the other end of the DBM substrate 502. In operation, the first power tab 520-1 can be a negative direct current terminal (DC−), the second power tab 522-1 can be a positive direct current terminal (DC+), and the third power tab 524-1 can be an output terminal (e.g. an AC terminal), so that current flows from the third power tab 524-1 to the first power tab 520-1, and from the second power tab 522-1 to the third power tab 524-1.

As shown in FIG. 5A, portions of the metal strips (e.g., metal strip 520, metal strip 522, and metal strip 524) extending from the edges of the substrate on to the substrate may have the shape of a two-legged prong (e.g., with two prong extensions) or two two-legged prongs (i.e., with four prong extensions). For example, metal strip 524 may include two prong extensions 524A and 524B with the ends of the extensions of the prongs corresponding to the second ends of the metal strip 524. As shown in at least FIG. 5A, the prong extension 524A and/or the prong extension 524B have a curved shape. Metal strip 520 may include four prong extensions 520A, 520B, 520C and 520D, with the ends of the extensions of the prongs corresponding to the second ends of the metal strip 520. Metal strip 522 also may include four prong extensions (e.g., prong extensions 522A, 522B, 522C and 522D) with the ends of the extensions of the prongs corresponding to the second ends of the metal strip 522.

In example implementations, the chip assembly 503 (or different devices therein) disposed on an upper portion (e.g., portion 502U) of DBM substrate 502 may form a high side switch coupling the input at the power tab 522-1 (positive direct current terminal (DC+) to the output at the third power tab 524-1 (AC terminal). Further, the chip assembly 503 (or different devices therein) disposed on a lower portion (e.g., portion 502L) of DBM substrate 502 may form a low side switch coupling the input at the power tab 522-1 (negative direct current terminal (DC−)) to the output at the third power tab 524-1 (AC terminal).

It is noted that the four prong extensions of metal strip 520 (i.e., prong extensions 520A, 520B, 520C and 520D) associated with a negative direct current terminal (DC−) (first power tab 520-1) are parallel to each other. Similarly, the four prong extensions of metal strip 522 (i.e., prong extensions 522A, 522B, 522C and 522D) associated with a positive direct current terminal (DC+)(power tab 522-1) are parallel to each other. This parallelism of splitting the DC current on metal strip 520 over the four parallel routes (i.e., prong extensions 520A, 520B, 520C and 520D) can improve current balance in the circuit. Similarly, the parallelism of splitting the DC current on metal strip 522 over the four parallel routes (e.g., prong extensions 522A, 522B, 522C and 522D) can improve current balance in the circuit.

In some implementations (and as shown in at least FIG. 5A) one or more of the prong extensions 520A, 520B, 520C and 520D are longer than one or more of the prong extensions 522A, 522B, 522C and 522D. In some implementations (and as shown in at least FIG. 5A) one or more of the prong extensions 520A, 520B, 520C and 520D has a same width as one or more of the prong extensions 522A, 522B, 522C and 522D.

In some implementations (and as shown in at least FIG. 5A), the prong extension 524A and/or the prong extension 524B has a width greater than a width of one or more of the prong extensions 520A, 520B, 520C and 520D. In some implementations (and as shown in at least FIG. 5A), the prong extension 524A and/or the prong extension 524B has a width greater than a width of one or more of the prong extensions 522A, 522B, 522C and 522D.

In some implementations (and as shown in at least FIG. 5A) one or more of the first power tab 520-1, second power tab 522-1, and/or third power tab 524-1 has a same width. In some implementations, one or more of the first power tab 520-1, second power tab 522-1, and/or third power tab 524-1 has different width than another of the first power tab 520-1, second power tab 522-1, and/or third power tab 524-1.

All of the second ends of metal strip 520, metal strip 522 and metal strip 524 may be attached (e.g., soldered or welded) at various locations to the substrate.

As shown in at least FIG. 5A, the metal strip 520 has at least a portion (e.g., portion 520-2 disposed above and aligned parallel to at least a portion of the metal strip 522. As shown in at least FIG. 5A, the metal strip 520 has at least first power tab 520-1 disposed above and aligned parallel to at least second power tab 522-1 of the metal strip 522. As shown in at least FIG. 5A, the metal strip 520 has at least a portion 520-2 disposed above and/or aligned parallel to a portion 522-2 of the metal strip 522. The metal strip 520 and/or the metal strip 522 are aligned parallel to the DBM substrate 502.

As shown in at least FIG. 5A, the metal strip 520 has a portion disposed above and aligned parallel to at least a portion of the metal strip 524. As shown in at least FIG. 5A, the metal strip 520 has at least first power tab 520-1 disposed above and aligned parallel to at least third power tab 524-1 of the metal strip 524.

As shown in at least FIG. 5A, the metal strip 522 has a portion disposed within a same plane as at least a portion of the metal strip 524.

In example implementations, a power circuit includes a chip assembly disposed on a top surface of a direct bond metal (DBM) substrate. The power circuit includes a first metal strip having a first end extending beyond a first edge of the substrate as a negative direct current power terminal disposed at the first edge. The first metal strip has multiple parallel extensions extending from the first edge to respective second ends attached to the substrate.

The power circuit further includes a second metal strip having a first end extending beyond the first edge of the substrate as a positive direct current power terminal disposed at the first edge. The second metal strip has multiple parallel extensions extending from the first edge to respective second ends attached to the substrate.

The power circuit further includes a third metal strip having a first end extending beyond a second edge of the substrate, opposite the first edge, as an alternating current power terminal disposed at the second edge. The third metal strip has multiple parallel extensions extending from the second edge to respective second ends attached to the substrate.

The first, second and third metal strips confine current in the power circuit to flow in parallel paths along the respective multiple parallel extensions. This parallelism can improve the current balance in the power circuit.

The power circuit may further include signal pins that may be attached to traces on the substrate for receiving signals from, or sending signals to, external systems (e.g., monitoring or control systems).

Signal pins that have fixtures (e.g., flange 107) to prevent mold bleed during lateral molding processes can be used when molding or encapsulating power circuit 500, for example, in a lateral molded package. FIG. 5A shows, for example, several pins, such as pin 100C (FIG. 1B), that are vertically oriented and attached to DBM substrate 502 before the lateral or injection molding process. As shown in FIG. 5A, the pin 100C attached to DBM substrate 502 is vertically aligned and has a flange 107 (FIG. 1B) (e.g., a spring-loaded flange) to prevent mold bleed during the lateral or injection molding process.

FIG. 5B is a perspective top view of a molded casing of a package encapsulating a power circuit (e.g., the power circuit 500 shown in FIG. 5A), according to implementations of the present disclosure. FIG. 5B shows a molded casing 500M that has a generally rectangular shape with a length L, a width W and a height H. The power circuit 500 (e.g., enclosed power circuit) is not visible because it is encapsulated in mold compound 205. However, FIG. 5B shows the external power terminals - first power tab 520-1 (positive direct current terminal (DC+)), power tab 522-1 (negative direct current terminal (DC−), and power tab 524-1 (AC terminal), extending outside the rectangular shaped body of molded casing 500M. FIG. 5B also shows the body regions (body region 101) and tip regions (tip region 102A) of the pin 100C (e.g., vertically-aligned pin) extending above the top surface TS of the molded casing 500M.

FIG. 5C is a perspective bottom side view of the molded casing 500M of FIG. 5B, according to implementations of the present disclosure.

As shown in FIG. 5C, a window (e.g., window 500W) in the back surface or molded casing 500M exposes a bottom surface BS of DBM substrate 502, on the front surface of which power circuit 500 encapsulated in molded casing 500M. The exposed bottom surface BS of DBM substrate 502 provides a pathway for dissipating heat generated by power circuit 500. Thus, molded casing 500M may be configured as a SSDC package.

In some implementations, a metal base plate (not shown) may be attached to the exposed bottom surface BS of DBM substrate 502. In example implementations, the metal base plate includes a heat sink (not shown). The heat sink can be immersed in a cooling fluid to provide faster heat dissipation.

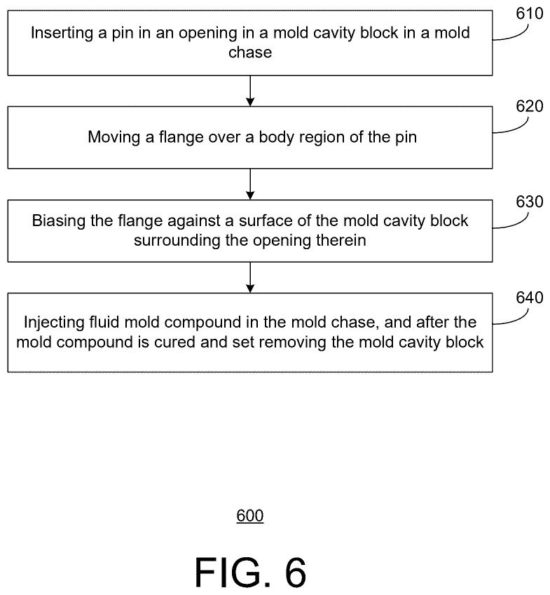

FIG. 6 illustrates an example method 600 for preventing or reducing mold bleed around a pin that extends through an opening in a mold cavity block during a lateral transfer or injection molding process.

Method 600 inserting the pin in an opening (e.g., hole) in a mold cavity block in a mold chase (610), moving (e.g., sliding) a flange (e.g., an annular flange) over a cylindrical body of the pin (620), and biasing the flange against a surface of the mold cavity block surrounding the opening therein (630).

In example implementations, the pin may have a base region attached (e.g., soldered or welded) to a substrate. The flange may have an outer diameter that is larger than a diameter of the opening in the mold cavity block. In example implementations, the flange may be attached to a top of a tubular moving component that can slide over a cylindrical body of the pin.

In method 600, biasing the flange against the surface of the mold cavity block surrounding the opening therein, can include disposing a biasing component (e.g., a helical spring) on the moving component, and compressing the biasing component to bias the flange against the surface of the mold cavity block. Further, compressing the biasing component to bias the flange against the surface of the mold cavity block may include holding the biasing component in a compressed state utilizing a biasing component stopper attached a base region of the pin.

In some implementations, the moving component may be deformable. The moving component may include an annular tube-like structure. A lower edge E of the annular tube-like structure may be slit, for example, with multiple slits S running parallel to the length of the moving component. These slits may allow the annular tube-like structure of the moving component to be deformed (e.g., flared outward), for example, when the moving component is slid over a taper TA in the diameter of the cylindrical body of the pin. The deformed moving component may be held in place by a friction fit over the taper TA.

In method 600, biasing the flange against the surface of the mold cavity block may include deforming the moving component to hold it in a fixed position while the flange attached to the top of the moving component contacts (e.g., is pressed against) the surface of the top mold cavity block.

Method 600 may further include injecting fluid mold compound in the mold chase, and after the mold compound is cured and set, removing the mold cavity block (640).

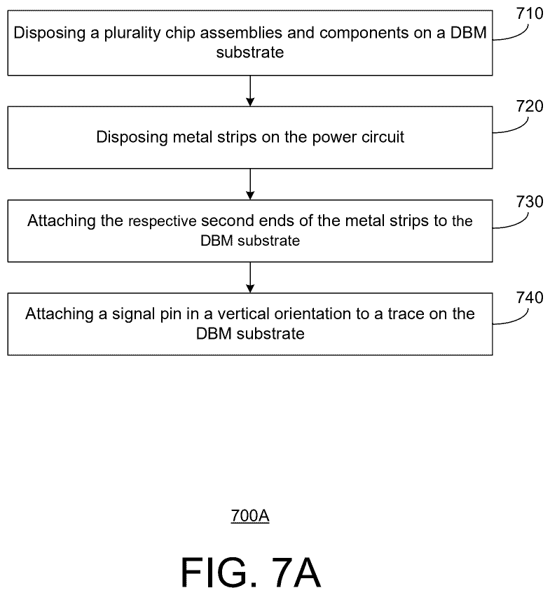

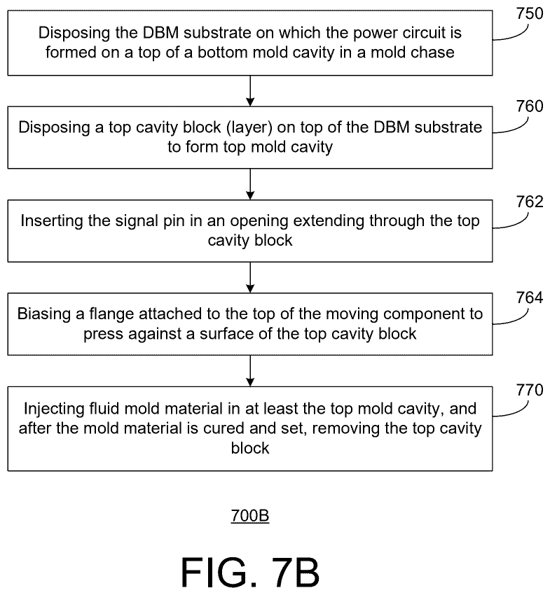

FIG. 7A illustrates a method 700A for fabricating a power circuit (e.g., power circuit 500), and FIG. 7B illustrates a method 700B for packaging the power circuit in a SSDC package (e.g., molded casing 500M), in accordance with some implementations of the present disclosure.

Method 700A for fabricating a power circuit includes disposing a chip assembly (e.g., a plurality chip assemblies) on a DBM substrate (710). In some implementations, components, in addition to, or other than the chip assembly. The chip assembly may, for example, include chip assembly 503, a thermistor 504, etc. In example implementations, the chip assembly 503 can be attached to, e.g., mounted on, or coupled to, a top surface of the DBM substrate 502 by a copper sputtering process or by a bonding agent, e.g., an epoxy, a solder, a silver (Ag) sintering material, and/or an adhesive. In example implementations, several of the chip assembly are interconnected, for example, by wire bonds 505 or conductive metal clips (not shown).

Method 700A further includes disposing metal strips on the power circuit (720). The metal strips (e.g., metal strip 520, metal strip 522 and metal strip 524) can have first ends that extend beyond the edges of substrate to form power tabs (e.g., a first power tab 520-1, a second power tab 522-1, and a third power tab 524-1) that may serve as the external terminals of the power circuit encapsulated in a molded package (e.g., molded casing 500M, FIG. 5B). Each metal strip may have multiple branches or extensions, which may be parallel. Each metal strip may have multiple distal ends (second ends) (i.e., corresponding to ends of multiple branches or extensions). Method 700A includes attaching the respective second ends of the metal strips to the DBM substrate (730). The second ends may be attached to the substrate at various locations. Attaching the second ends of the metal strips includes soldering or welding the second ends to the substrate at the various locations.

In some implementations, a first power tab 520-1 and a second power tab 522-1 are disposed on one end of the DBM substrate 502 and the third power tab 524-1 is disposed on the other end of the DBM substrate 502. The first power tab 520-1 can be a negative direct current terminal (DC−), the second power tab 522-1 can be a positive direct current terminal (DC+), and the third power tab 524-1 can be an output terminal (e.g. an AC terminal), so that current flows from the third power tab 524-1 to the first power tab 520-1, and from the second power tab 522-1 to the third power tab 524-1.

The distal extensions of the metal strips (e.g., metal strip 520, metal strip 522 and metal strip 524) extending from the edges of the substrate on to the substrate may have the shape of a two-legged prong (i.e., a prong with two extensions) or two two-legged prongs (i.e., prongs with four extensions). The prong extensions may be parallel to each other. In method 700A, attaching the respective second ends of the metal strips to the DBM substrate 730 includes attaching ends of the prong extensions of the metal strips (e.g., metal strip 520, metal strip 522 and metal strip 524) to various locations on the substrate.

In example implementations, the chip assembly 503 disposed on an upper portion (e.g., portion 502U) of DBM substrate 502 may form a high side switch coupling the input at the power tab 522-1 (positive direct current (DC+) terminal) to the output at the third power tab 524-1 (AC terminal). Further, the chip assembly 503 disposed on a lower portion (e.g., portion 502L) of DBM substrate 502 may form a low side switch coupling the input at the power tab 522-1 (negative direct current (DC−) terminal) to the output at the third power tab 524-1 (AC terminal).

The parallelism of the distal extensions (prong extensions) can split DC current flow over the substrate in parallel paths and improve current balance in the circuit.

Method 700A further includes attaching a signal pin in a vertical orientation to a trace on the DBM substrate (740). This may include attaching several signal pins in a vertical orientation at several locations on the DBM substrate. The signal pins (e.g., pin 100B, pin 100C, pin 300A, pin 300B, etc.) may include features (e.g., annular flanges) that can be biased against a surface of a mold cavity block to seal openings through which the pins are positioned in lateral or transfer molding processes.

Attaching a signal pin on the DBM substrate 502 may include soldering or welding the base of the signal pin to a trace on the DBM substrate. In some implementations, attaching a signal pin on the DBM substrate 502 may include pressure fitting the base of the pin in an opening (e.g., hole) in the DBM substrate 502. The signal pin may include a flange attached to a top of a moving component sliding on a central region of the signal pin.

Method 700B for packaging the power circuit in a SSDC package (e.g., molded casing 500M) includes disposing the DBM substrate (e.g., substrate) on which the power circuit is formed on a top of a bottom mold cavity in a mold chase (750). Method 700B may further include disposing a top cavity block (layer) on top of the DBM substrate to form a top mold cavity (760). Placing the top cavity block on the top of the substrate may include inserting (which can include aligning) the signal pin in an opening (e.g., a hole) extending through the top cavity block (762) and biasing the flange attached to the top of the moving component to contact (e.g., press against) a surface of the top cavity block (764). The flange attached to a top of a moving component and contacting (e.g., pressed against) the surface of the top cavity block may seal the opening and prevent mold bleed (e.g., along sides of the signal pin) of fluid mold material injected in the top mold cavity.

In method 700B, biasing the flange against the surface of the top cavity block 764 may include compressing a biasing component surrounding the moving component by pushing down, or weighing down, the top cavity block, or in the case of a deformable moving component, deforming the moving component by pushing down the top cavity block to hold the moving component in fixed position on a taper in the central region of the signal pin.

Method 700B further includes injecting fluid mold material in at least the top mold cavity, and after the mold material is cured and set, removing the top cavity block (770).

In some implementations, a DBM substrate can be formed by bonding one or more of the metal layers (e.g., first metal layer, second metal layer) to the insulating layer. In some implementations, one or more of the metal layers can be bonded to the insulating layer using, for example, a high-temperature process.

In some implementations, the first metal layer and/or the second metal layer of the DBM substrate can be or can function as a heat sink. In some implementations, the first metal layer and/or the second metal layer can be coupled to a heat sink. In some implementations, at least a portion of one or more of the first metal layer or the second metal layer can be exposed through a molding material.

In some implementations, the first metal layer and/or the second metal layer of the DBM substrate can be or can include a patterned metal layer including one or more electrically conductive traces. In some implementations, the first metal layer and/or the second metal layer can be or can include a patterned layer configured to form one or more electrical circuits, one or more conductive blind and/or through vias, and/or so forth.

In some implementations, the DBM substrate can be, or can include a direct bonded copper (DBC) substrate (e.g., a DBM with copper metal layers). In some implementations, such as in DBC substrate implementations, the first metal layer and/or the second metal layer is a copper layer.

In some implementations, one or more semiconductor dies (e.g., one or more semiconductor components) can be, or can include, a power semiconductor die. In some implementations, one or more semiconductor die can be (e.g., can be a portion of), or can include, one or more of a metal-oxide-semiconductor field-effect transistor (MOSFET) device, an insulated-gate bipolar transistor (IGBT), an integrated circuit (IC), an inverter, a power conversion circuit, a bridge circuit, a fast recovery diode (FRDs), a diode, and/or so forth. In some implementations, one or more semiconductor die can be (e.g., can be a portion of), or can include a component for an electrical vehicle (EV).

More than one semiconductor die can be included in the implementations described herein. In some implementations, different semiconductor die (when more than one semiconductor die is included in some of the implementations) can be fabricated using different semiconductor substrates (e.g., a silicon carbide (SiC) substrate, a silicon (Si) substrate, a gallium nitride (GaN) substrate). In other words, different semiconductor die may, for example, be fabricated on different semiconductor wafers or materials. This can be referred to as a hybrid die configuration. For example, a first semiconductor die can be formed using a SiC substrate and a second semiconductor die (separate from the first semiconductor die) can be formed using a silicon substrate. As another example, an IGBT can be fabricated using a SiC substrate, while a controller can be fabricated using a silicon substrate.

In example implementations, a first semiconductor die may be connected to a second of the semiconductor die, for example, by an electrical connection (e.g., a wire bond, an electrical clip) extending directly from the first die to the second die, or connected through a trace formed in the first conductive layer (e.g., a metal layer) of an electronic power substrate. The first of the plurality of semiconductor die may be also connected to lead frame posts by electrical connections such as wire bonds or clips.

In example implementations, a package (e.g., a power module) can be a hybrid device package that includes a semiconductor die or a plurality of semiconductor die that are integrated onto to a unifying electronic power substrate (e.g., a ceramic substrate, a DBM or DBC substrate, an AMB substrate). In some implementations, multiple semiconductor devices (e.g., can be fabricated on the same substrate such as a SiC substrate) suitable for high power applications.

In some implementations, a molding compound (e.g., molding material or compound, an encapsulation material) can be or can include a non-conducting layer/material. In some implementations, the molding compound is a non-conducting material, such as an epoxy, which can be formed (applied, etc.) using a transfer molding process or a compression molding process. In some implementations, the molding compound can include a separate plastic housing that is included in the semiconductor device assembly.

One or more wire bonds, which can be included in at least some of the implementations described herein, can be replaced with a conductive component. For example, in some implementations, one or more wire bonds can be replaced with a conductive clip. The conductive clip can be coupled to another component (e.g., an attach pad, a leadframe, a semiconductor die, and/or so forth) using, for example, a solder (e.g., a soldering process), a sintered coupling (e.g., a sintering process), a weld, and/or so forth. In some implementations, one or more wire bonds and/or clips can function as an input and/or output power terminal, a signal terminal, a power terminal, and/or so forth.

In some implementations, one or more semiconductor die can be embedded within a layer (rather than surface mounted). For example, one or more semiconductor die can be disposed within a recess (also can be, or can be referred to as a cavity) of a layer (e.g., a substrate, a printed circuit board, a conductive layer, an insulating layer).

In some implementations, a spacer material can be an epoxy, a silicone adhesive, a conductive material, a non-conductive material, an organic material, a semiconductor material, a metal alloy, a metal foam, a phase change material, etc.

In some implementations, a module (e.g., a package including a semiconductor device) can be included in another module. The module can be referred to as a package. For example, one or more modules can be one or more sub modules included within another module. In other words, a first module can be included as a sub module within a second module.

It will be understood that, in the foregoing description, when an element, such as a layer, a region, or a substrate, is referred to as being on, connected to, electrically connected to, coupled to, or electrically coupled to another element, it may be directly on, connected or coupled to the other element, or one or more intervening elements may be present. In contrast, when an element is referred to as being directly on, directly connected to or directly coupled to another element or layer, there are no intervening elements or layers present. Although the terms directly on, directly connected to, or directly coupled to may not be used throughout the detailed description, elements that are shown as being directly on, directly connected or directly coupled can be referred to as such. The claims of the application may be amended to recite exemplary relationships described in the specification or shown in the figures.

In some implementations, soldering can be, or can include a process of joining two surfaces (e.g., metal surfaces) together using a molten filler metal (e.g., metal alloy, Tin (Sn), Lead (Pb), Silver (Ag), Copper (Cu)) that can be referred to as a solder.

In some implementations, sintering can be or can include a process of fusing particles together into one solid mass by using, for example, a combination of pressure and/or heat without melting the materials. In some implementations, sintering can include making a material (e.g., a powdered material) coalesce into a solid or porous mass by heating it, and usually also compressing the material, without liquefaction. In some implementations, materials that can be used for sintering can include metals such as silver (Ag), copper (Cu) and/or metal alloys. In some implementations, sintered connections can have desirable electrical and/or thermal conductivity, durability, and a relatively high melting temperature.

In some implementations, one or more of the components described herein can be coupled using materials such as, for example, a solder, a sintering (e.g., silver, copper) material, and/or other metal-to-metal type bonding materials.

In some implementations, a coupling of components can be performed using, for example, a solder process, a sintering process (e.g., a silver sintering process, a copper sintering process), and/or other metal-to-metal type bonding processes.

As used in this specification, a singular form may, unless definitely indicating a particular case in terms of the context, include a plural form. Spatially relative terms (e.g., over, above, upper, under, beneath, below, lower, top, bottom, and so forth) are intended to encompass different orientations of the device in use or operation in addition to the orientation depicted in the figures. In some implementations, the relative terms above and below can, respectively, include vertically above and vertically below. In some implementations, the term adjacent can include laterally adjacent to or horizontally adjacent to.

Some implementations may be implemented using various semiconductor processing and/or packaging techniques. Some implementations may be implemented using various types of semiconductor device processing techniques associated with semiconductor substrates including, but not limited to, for example, silicon (Si), silicon carbide (SiC), gallium arsenide (GaAs), gallium nitride (GaN), and/or so forth.

While certain features of the described implementations have been illustrated as described herein, many modifications, substitutions, changes, and equivalents will now occur to those skilled in the art. For instance, features illustrated with respect to one implementation can, where appropriate, also be included in other implementations. It is, therefore, to be understood that the appended claims are intended to cover all such modifications and changes as fall within the scope of the implementations. It should be understood that they have been presented by way of example only, not limitation, and various changes in form and details may be made. Any portion of the apparatus and/or methods described herein may be combined in any combination, except mutually exclusive combinations. The implementations described herein can include various combinations and/or sub-combinations of the functions, components and/or features of the different implementations described.

1. An apparatus, comprising:
a base;
a tip;
a body region, the body region being disposed between the base and the tip;
a flange disposed on a top of a moving component configured to slide on the body region; and
a biasing component coupled to the moving component; the biasing component configured to bias the flange upward against a surface.

2. The apparatus of claim 1, wherein a stopper is attached to the base and configured to lock the biasing component in a compressed position for biasing the flange against the surface.

3. The apparatus of claim 1, wherein the base is configured to be attached to a trace on a substrate.

4. The apparatus of claim 1, wherein the tip includes a compressible structure including at least one of a taper structure and a needle eyelet structure.

5. The apparatus of claim 1, wherein at least one of the flange, the moving component, and the biasing component are made of at least one of a plastic, a metal, or a metal alloy.

6. The apparatus of claim 1 disposed on an electronic substrate encapsulated in a mold body, at least a portion of the apparatus extending in vertical orientation from a top surface of the mold body.

7. An apparatus, comprising:
a base;
a tip;
a body region disposed between the base and the tip, the body region having a cylindrical shape; and
a flange disposed on a top of a deformable moving component that is configured to slide on the body region,
the deformable moving component in a deformed state being in a fixed position to bias the flange upward against a surface.

8. The apparatus of claim 7, wherein the deformable moving component has an annular tube-like structure with a length, a lower edge E of the annular tube-like structure having a plurality of slits aligned parallel to the length of the deformable moving component.

9. The apparatus of claim 8, wherein the body region has an upper portion having a first diameter, a lower portion having a second diameter greater than the first diameter, and a taper region of increasing diameter between the upper portion and the lower portion, and wherein the deformable moving component is deformed and held in a fixed position with the flange pressing upward against a surface when the deformable moving component is slidably moved over the taper region.

10. The apparatus of claim 7, wherein the tip includes a compressible structure including at least one of a taper structure and a needle eyelet structure.

11. The apparatus of claim 7 disposed on an electronic substrate encapsulated in a mold body, at least a portion of the apparatus extending in vertical orientation from a top surface of the mold body.

12. A power circuit comprising:
a chip assembly disposed on a top surface of a direct bond metal (DBM) substrate;
a first metal strip having a first end extending beyond a first edge of the DBM substrate as a negative direct current power terminal disposed at the first edge, the first metal strip having multiple parallel extensions extending from the first edge to respective second ends attached to the DBM substrate;
a second metal strip having a first end extending beyond the first edge of the DBM substrate as a positive direct current power terminal disposed at the first edge, the second metal strip having multiple parallel extensions extending from the first edge to respective second ends attached to the DBM substrate; and
a third metal strip having a first end extending beyond a second edge of the DBM substrate, opposite the first edge, as an alternating current power terminal disposed at the second edge, the third metal strip having multiple parallel extensions extending from the second edge to respective second ends attached to the DBM substrate,
the first, second, and third metal strips confining current in the power circuit to flow in parallel paths along the respective multiple parallel extensions.

13. The power circuit of claim 12 further comprising:
at least one signal pin attached, in a vertical orientation, to a trace on the DBM substrate.

14. The power circuit of claim 13, wherein the at least one signal pin includes a fixture to prevent mold bleed during lateral molding processes.

15. The power circuit of claim 14, further encapsulated in a mold body with at least a portion of the signal pin extending in a vertical orientation from a top surface of the mold body.

16. The power circuit of claim 12, wherein at least one of the chip assembly includes an insulated-gate bipolar transistor (IGBT).

17. The power circuit of claim 12, wherein the chip assembly disposed on an upper portion of the DBM substrate form a high side switch coupling an input at the positive direct current power terminal to an output at the alternating current terminal, and the chip assembly disposed on a lower portion of the DBM substrate form a low side switch coupling an input at the negative direct current terminal to the output at the alternating current terminal.

18. The power circuit of claim 12, further comprising a thermistor.

19. A method comprising:
inserting a pin in an opening in a mold cavity block in a mold chase;
sliding a flange over a body region of the pin; and
biasing the flange against a surface of the mold cavity block surrounding the opening therein.

20. The method of claim 19, wherein the flange is attached to a top of a moving component, and wherein biasing the flange against the surface of the mold cavity block includes:
disposing a spring on the moving component and compressing the biasing component to bias the flange against the surface of the mold cavity block.

21. The method of claim 20, wherein compressing the biasing component to bias the flange against the surface of the mold cavity block includes holding the biasing component in a compressed state utilizing a biasing component stopper attached a base region of the pin.

22. The method of claim 19, wherein the flange is attached to a top of a moving component that is deformable, and wherein biasing the flange against the surface of the mold cavity block includes: deforming the moving component to hold it in a fixed position while the flange attached to the top of the moving component is contacting the surface of the mold cavity block.

23. A method comprising:
disposing a chip assembly and components on a direct bond metal (DBM) substrate to form a power circuit;
disposing metal strips on the power circuit, the metal strips having first ends that extend beyond edges of DBM substrate to serve as external terminals of the power circuit when encapsulated in a molded package, each metal strip having multiple parallel extensions with respective second ends;
attaching the respective second ends of the metal strips to the DBM substrate;
attaching a signal pin in a vertical orientation to a trace on the DBM substrate, the signal pin including a flange attached to a top of a moving component sliding on a body region of the signal pin;
disposing the DBM substrate on which the power circuit is formed on a top of a bottom mold cavity in a mold cavity chase;
disposing a top cavity block on top of the DBM substrate to form a top mold cavity;
aligning and inserting the signal pin in an opening extending through the top cavity block;
biasing a flange attached to a top of the moving component to press against a surface of the top cavity block;
injecting fluid mold material in at least the top mold cavity; and
after the fluid mold material is cured and set, removing the top cavity block.
